(19) United States
(12) Patent Application Publication
(10) Pub. No.: US 2015/0274510 A1
(43) Pub. Date: Oct. 1, 2015

(54) CAP MODULE FOR MICRO ELECTRO MECHANICAL SYSTEM AND MICRO ELECTRO MECHANICAL SYSTEM SENSOR HAVING THE SAME

(71) Applicant: SAMSUNG ELECTRO-MECHANICS CO., LTD., Gyeonggi-Do (KR)

(72) Inventors: Jae Chang LEE, Gyeonggi-Do (KR); Jong Hyeong SONG, Gyeonggi-Do (KR); Jong Woon KIM, Gyeonggi-Do (KR); Hyun Kee LEE, Gyeonggi-Do (KR)

(73) Assignee: SAMSUNG ELECTRO-MECHANICS CO., LTD., Gyeonggi-Do (KR)

(21) Appl. No.: 14/265,760

(22) Filed: Apr. 30, 2014

(30) Foreign Application Priority Data
Nov. 29, 2013 (KR) 10-2013-0147556

(51) Int. Cl. B81B 7/00

(52) U.S. Cl. CPC B81B 7/0058

(57) ABSTRACT

Embodiments of the invention provide a cap module for MEMS including a substrate, a first negative photoresist, which is formed on one surface of the substrate, and a second negative photoresist, which is formed on one surface of the first negative photoresist.

### CROSS REFERENCE TO RELATED APPLICATION

This application claims the benefit of and priority under 35 U.S.C. §119 to Korean Patent Application No. KR 10-2013-0147556, entitled “Cap Module For Micro Electro Mechanical System And Micro Electro Mechanical System Sensor Having The Same,” filed on Nov. 29, 2013, which is hereby incorporated by reference in its entirety into this application.

### BACKGROUND

1. Field of the Invention

The present invention to a cap module for a micro electro mechanical system (MEMS) and a micro electro mechanical system (MEMS) having the same.

2. Description of the Related Art

Recently, a micro electro mechanical system (MEMS) sensor has been used in various fields, for example, the military, such as an artificial satellite, a missile, an unmanned aircraft, or the like, vehicles, such as an air bag, electronic stability control (ESC), a black box for a vehicle, or the like, hand shaking prevention of a camcorder, motion sensing of a mobile phone or a game machine, navigation, or the like.

The MEMS sensor, as described, for example, in U.S. Pat. No. 7,204,737, generally adopts a configuration in which a mass body is bonded to an elastic substrate, such as a membrane, in order to measure acceleration and angular velocity.

Further, when a final packaging is performed in manufacturing the MEMS sensor, wafers having a predetermined thickness are machined and bonded to an upper portion and a lower portion of a device wafer at a wafer level so as to protect devices. The wafer is generally defined by a cap wafer.

Further, the cap wafer is subjected to a separate manufacturing process from a device wafer process. In this case, after an upper portion and a lower portion of a cavity are provided with cavities at a predetermined depth using a wet etching or a dry etching depending on an upper cap or a lower cap, a lower cap wafer is first bonded and an upper cap wafer is then bonded again, using a dry film as an adhesive layer.

When the device wafer is manufactured by the above method, three processes of forming the cavity, patterning the dry film, and bonding the dry film to the device wafer are performed to manufacture the cap wafer. When all the three processes are applied to the upper/lower cap wafers, a lot of time and costs are required.

Further, when an adhesion between the cap wafer and the dry film are degraded depending on a surface state of the wafer, there is a problem in that the cap wafer used during the process is discarded and then needs to be manufactured again.

### SUMMARY

Accordingly, embodiments of the present invention provide a cap module for MEMS, which may have a reduced defective rate, an elaborate structure, and improved productivity by forming an adhesive for coupling a cap with a MEMS device, while forming a cavity by a first negative photoresist and a second negative photoresist.

Further, the present invention has been made in an effort to provide a MEMS sensor, which includes an upper cap and a lower cap including a substrate, a first negative photoresist and a second negative photoresist to ensure an accurate cavity depth to improve sensing capability and is elaborately coupled with a sensor part to improve reliability.

According to an embodiment of the invention, there is provided a cap module for MEMS, including a substrate, a first negative photoresist, which is formed on one surface of the substrate, and a second negative photoresist, which is formed on one surface of the first negative photoresist.

According to an embodiment of the invention, the first negative photoresist and the second negative photoresist are each formed, so that space parts formed with cavities correspond to each other.

According to an embodiment of the invention, the space part is formed by applying the same mask to the first negative photoresist and the second negative photoresist, and exposing and developing the first negative photoresist and the second negative photoresist.

According to an embodiment of the invention, the first negative photoresist and the second negative photoresist are formed by spin coating and are formed to have a thickness by controlling an RPM.

According to an embodiment of the invention, the first negative photoresist is SU-8, which is an epoxy-based negative photoresist.

According to an embodiment of the invention, the second negative photoresist is liquid SINR.

According to another embodiment of the invention, there is provided a MEMS sensor, including a sensor part, and a cap module, which is coupled with the sensor part to cover the sensor part, wherein the cap module includes a substrate, a first negative photoresist formed on one surface of the substrate, and a second negative photoresist formed on one surface of the first negative photoresist.

According to an embodiment of the invention, the sensor part covered with the cap module includes a mass part, a flexible substrate, which is displaceably coupled with the mass part; and a support part, which is coupled with the flexible substrate and floatably supports the mass part.

According to an embodiment of the invention, the cap module covers the flexible substrate and includes an upper cap, which is coupled with the flexible substrate and a lower cap, which covers the mass part and is coupled with the support part.

According to an embodiment of the invention, the second negative photoresist of the upper cap is coupled with the flexible substrate, and the second negative photoresist of the lower cap is supported with the support part.

According to an embodiment of the invention, the first negative photoresist and the second negative photoresist are each formed to face each other in the sensor part, so that space parts formed with cavities are formed to correspond to each other.

According to an embodiment, the space part is formed by applying the same mask to the first negative photoresist and the second negative photoresist, and exposing and developing the first negative photoresist and the second negative photoresist.

According to an embodiment, the first negative photoresist and the second negative photoresist are formed by spin coating and are formed to have a thickness by controlling an RPM.

According to an embodiment, the first negative photoresist is SU-8, which is an epoxy-based negative photoresist.

According to an embodiment, the second negative photoresist is liquid SINR.

According to another embodiment of the invention, there is provided a MEMS sensor, including a sensor part, and a cap module, which is coupled with the sensor part to cover the sensor part, wherein the cap module includes a substrate, a first negative photoresist formed on one surface of the substrate, and a second negative photoresist formed on one surface of the first negative photoresist.

According to an embodiment, the sensor part is further provided with a frame, which is selectively connected to the flexible substrate, the support part, and the mass part and limits a displacement of the mass part or is displaceably supported to the support part.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIGS. 1A and 1B are cross-sectional views schematically illustrating a cap module for MEMS, in accordance with an embodiment of the invention, in which FIG. 1A illustrates a lower cap, and FIG. 1B illustrates an upper cap.

FIGS. 2A to 2F are cross-sectional views schematically illustrating a process of manufacturing the cap module for MEMS illustrated in FIG. 1, in accordance with an embodiment of the invention.

FIG. 3 is a cross-sectional view schematically illustrating a MEMS sensor including a cap module, in accordance with an embodiment of the invention.

FIG. 4 is a cross-sectional view schematically illustrating a MEMS sensor including a cap module, in accordance with another embodiment of the invention.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

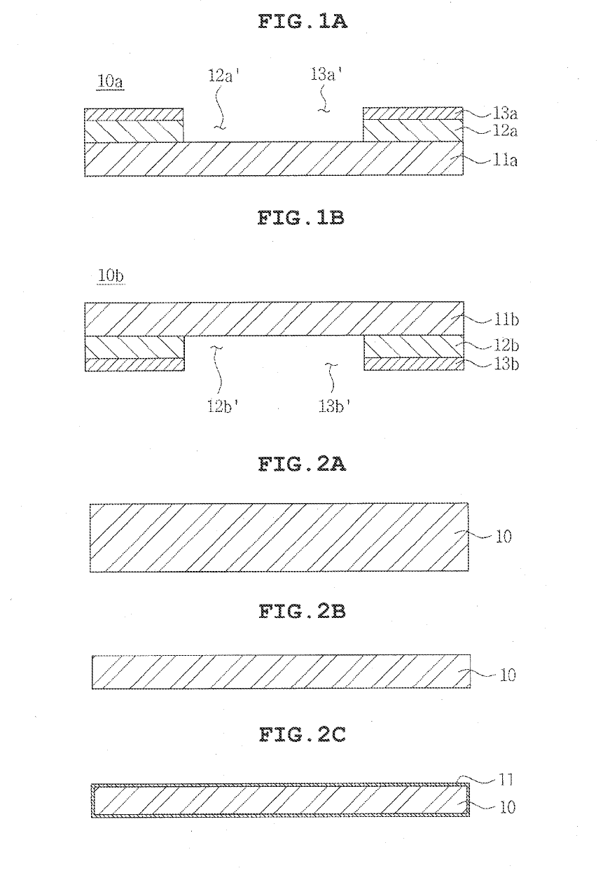

FIGS. 1A and 1B are cross-sectional views schematically illustrating a cap module for MEMS, in accordance with an embodiment of the invention, in which FIG. 1A illustrates a lower cap and FIG. 1B illustrates an upper cap.

As illustrated, a lower cap 10a, which is the cap module for MEMS, includes a substrate 11a, a first negative photoresist 12a, and a second negative photoresist 13a.

In more detail, the first negative photoresist 12a is to form a cavity when the lower cap 10a is coupled with the MEMS device and is formed on one surface of the substrate 11a.

Further, according to an embodiment, the second negative photoresist 13a is to be formed as an adhesive to couple the lower cap 10a with the MEMS device and is formed on one surface of the first negative photoresist 12a.

Therefore, in accordance with at least one embodiment, the lower cap 10a has a structure in which the first negative photoresist 12a is stacked on the substrate 11a and the second negative photoresist 13a is stacked on the first negative photoresist 12a.

Further, the first negative photoresist 12a and the second negative photoresist 13a are each formed with space parts 12a′ and 13a′ in which cavities are formed.

Further, the first negative photoresist 12a adopts SU-8, which is an epoxy-based negative photoresist and the second negative photoresist 13a adopts liquid SINR.

Next, an upper cap 10b, which is the cap module for MEMS, includes a substrate 11b, a first negative photoresist 12b, and a second negative photoresist 13b.

In more detail, the first negative photoresist 12b, according to at least one embodiment, is to form a cavity when the upper cap 10b is coupled with the MEMS device and is formed on one surface of the substrate 11b.

Further, the second negative photoresist 13b is to be formed as an adhesive to couple the upper cap 10b with the MEMS device and is formed on one surface of the first negative photoresist 12b.

Therefore, in accordance with at least one embodiment, the upper cap 10b has a structure in which the first negative photoresist 12b is stacked on the substrate 11b and the second negative photoresist 13b is stacked on the first negative photoresist 12b.

Further, the first negative photoresist 12b and the second negative photoresist 13b are each formed with space parts 12b′ and 13b′ in which cavities are formed.

Further, the first negative photoresist 12b adopts the SU-8, which is the epoxy-based negative photoresist and the second negative photoresist 13b adopts the liquid SINR.

By the above structure, the cap module for MEMS, according to an embodiment of the invention, has a reduced defective rate, an elaborate structure, and improved productivity by forming an adhesive for coupling the cap with the MEMS device while forming the cavities by the first negative photoresists 12a and 12b and the second negative photoresists 13a and 13b, which are formed on the substrate.

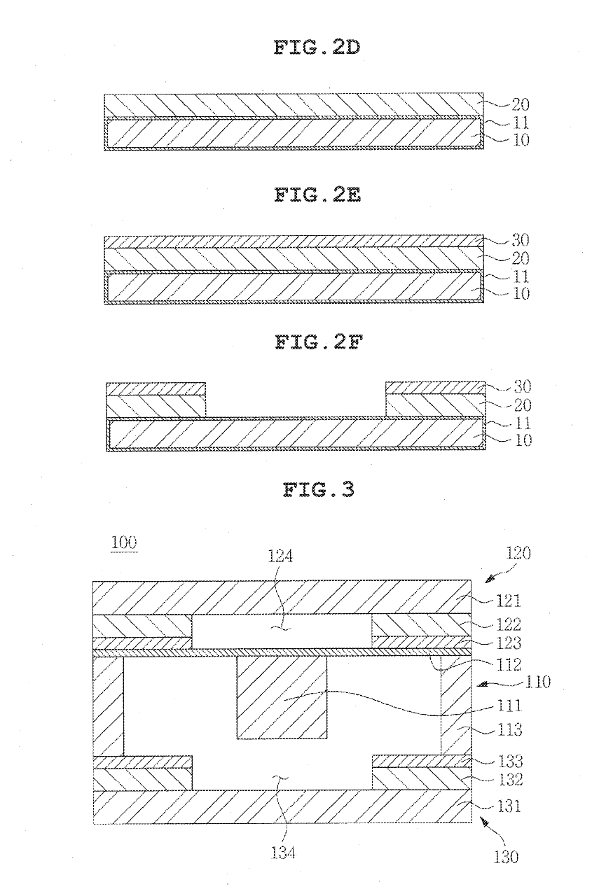

Hereinafter, a process of manufacturing a cap module for MEMS, according to various embodiments of the invention, will be described in more detail with reference to FIGS. 2A to 2F.

FIGS. 2A to 2F are cross-sectional views schematically illustrating a process of manufacturing the cap module for MEMS illustrated in FIG. 1, in accordance with an embodiment of the invention. As shown, FIG. 2A illustrates that a wafer 10 for forming the substrate of the cap module for MEMS is prepared, FIG. 2B illustrates that the wafer 10 is formed at a desired thickness, and FIG. 2C illustrates that an oxidation 11 is formed on the wafer 10.

Next, FIG. 2D illustrates that the first negative photoresist 20 is formed on one surface of the wafer 10 on which the oxidation 11 is formed. Further, FIG. 2E illustrates that the second negative photoresist 30 is formed on one surface of the first negative photoresist 20.

Further, the first negative photoresist 20 is formed by adopting and coating the SU-8. Further, the second negative photoresist 30 is formed by adopting and coating the liquid SINR.

Further, the SU-8, which is the first negative photoresist 20 and the liquid SINR, which is the second negative photoresist 30 are sequentially subjected to a coating process and a soft bake process to have a two-layer structure and are then subjected to an exposure process and a developing process, thereby forming the cap module for MEMS illustrated in FIG. 2F.

In more detail, the SU-8, which is the first negative photoresist 20 is coated, the SU— 8, which is the first negative photoresist 20 is subjected to the soft bake process, the liquid SINR, which is the second negative photoresist 30 is coated, and the liquid SINR, which is the second negative photoresist 30 is subjected to the soft bake process, thereby forming the cap module for MEMS, as illustrated in FIG. 2E. In this case, an RPM of a spin coater is controlled to control a thickness of the SU-8, which is the first negative photoresist 20 and a thickness of the liquid SINR, which is the second negative photoresist 30, such that a depth of the cavity is implemented to have a desired design value.

Next, according to an embodiment of the invention, the SU-8, which is the first negative photoresist 20 and the liquid SINR, which is the second negative photoresist 30 are exposed and developed using the same mask for forming the cavity, thereby forming the cap module for MEMS, as illustrated in FIG. 2F.

In more detail, when the exposure is completed, the SINR, which is the second negative photoresist 30 is subjected to a post exposure bake (PEB) and is then developed in IPA, which is an SINR developer, and then an exposed portion of the SU-8, which is the first negative photoresist 20 is developed in an SU-8 developer using the SINR development. Further, the SINR, which is the second negative photoresist 30 is dipped in the IPA, which cleans the SU-8 developer.

As the cap module for MEMS, according to an embodiment of the invention, is manufactured by the above method, the occurrence of defects may be reduced, costs and time may be shortened, and productivity may be improved, as compared with the related art using a dry film resist or a polymer as an adhesive. Thus, as the above processes are continuously performed simultaneously by a photolithography process, a total time of 2 to 3 days required to manufacture the cap according to the related art is shortened to 1 day.

Further, the cap, according to the related art, requires a cap mask for a cavity and a DFR pattern and four masks as a bonding mask, but the cap module for MEMS, according to an embodiment of the invention, requires only two masks, such that costs are saved and the required time is shortened. Further, as the depth of the cavity is formed by the coating process rather than by the silicon etching process according to the related art, the depth of the cavity is easily controlled and the cavity is completely removed by a cleaning process at the time of the occurrence of defects and then the reprocess may be possibly performed, such that the cap module for MEMS has improved productivity.

Further, the cap, according to the related art, is made of Si, but as the cap module for MEMS, according to an embodiment of the invention, adopts the SU-8 having hardness lower than that of the Si, the cap module for MEMS is less affected by an external stress.

FIG. 3 is a cross-sectional view schematically illustrating a MEMS sensor including a cap module, in accordance with an embodiment of the invention. As illustrated in FIG. 3, a MEMS sensor 100 includes a sensor part 110 and a cap module which is coupled with the sensor part to cover the sensor part.

Further, in accordance with an embodiment, the cap module includes an upper cap 120 and a lower cap 130.

In more detail, the sensor part 110 includes a mass part 111, a flexible substrate 112, and a support part 113.

In accordance with an embodiment, the mass part 111 is displaced, for example, by a Coriolis force, and is displaceably coupled with the flexible substrate 112.

Further, the flexible substrate 112 is provided with a driving unit and/or a sensing unit, in which the driving unit and the sensing unit is not specifically limited, but may be formed to use, for example, a piezoelectric type, a piezoresistive type, a capacitive type, an optical type.

In accordance with an embodiment, the flexible substrate 112 is coupled with the mass part 111 by the support part 113, such that the mass part 111 is supported to float by the support part 113.

In accordance with an embodiment, the upper cap 120 is coupled with one surface of the flexible substrate to cover the flexible substrate 112 and the lower cap 130 is coupled with one surface of the support part 113 to cover the mass part 111.

In accordance with an embodiment, the upper cap 120 includes a substrate 121, a first negative photoresist 122, and a second negative photoresist 123.

In more detail, the first negative photoresist 122 is to ensure a formation space of the cavity and is formed on one surface of the substrate 121, which faces the sensor part 110.

In accordance with an embodiment, the first negative photoresist 122 adopts the SU—8, which is the epoxy-based negative photoresist.

In accordance with an embodiment, the second negative photoresist 123 is formed as an adhesive, which couples the upper cap 120 with the flexible substrate of the sensor part 110 and is formed on one surface of the first negative photoresist 122, which faces the sensor part 110.

In accordance with an embodiment, the second negative photoresist adopts the liquid SINR.

In accordance with an embodiment, the second negative photoresist 123 is coupled with one surface of the flexible substrate 112.

Next, the lower cap 130 is formed by the same technical configuration as the upper cap 120. In more detail, the lower cap 130 includes a substrate 131, a first negative photoresist 132, and a second negative photoresist 133 and each component is described with reference to the upper cap, and therefore the description thereof will be omitted.

In accordance with an embodiment, the second negative photoresist 133 is coupled with one surface of the support part 113.

In accordance with an embodiment, the first negative photoresist and the second negative photoresist of the upper cap 120 and the lower cap 130 are each formed to face each other in the sensor part, so that the space parts formed with cavities 124 and 134 are formed to correspond to each other. Thus, the cavity 124 of the upper cap 120 is formed to face the flexible substrate 122 and the cavity 134 of the lower cap 130 is formed to face the mass part 111.

In accordance with an embodiment, the first negative photoresists 122 and 222 and the second negative photoresists 123 and 223 are formed on the substrates 121 and 222 by the spin coating method and the thickness thereof and the depth of the cavity, which is limited by the thickness, is simply and elaborately implemented by changing the RPM.

In accordance with an embodiment, the cavities 124 and 134 are formed by applying the same mask to the first negative photoresists 122 and 222 and the second negative photoresists 123 and 223 and exposing and developing the first negative photoresists 122 and 222 and the second negative photoresists 123 and 223.

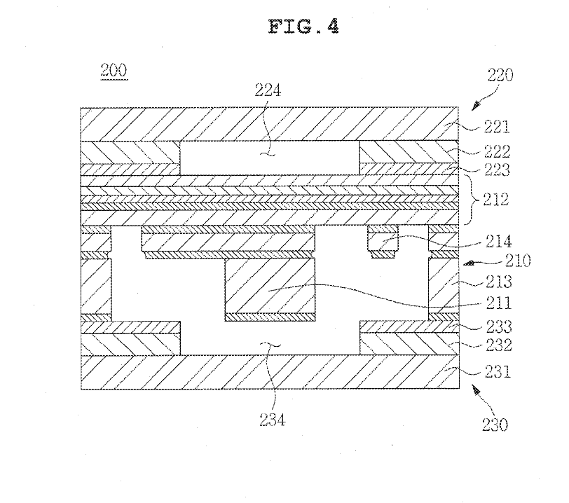

FIG. 4 is a cross-sectional view schematically illustrating a MEMS sensor including a cap module, in accordance with another embodiment of the invention. In more detail, compared with the MEMS sensor, according to the embodiment illustrated in FIG. 3, the MEMS sensor, according to another embodiment of the invention, has a configuration in which the sensor part is further provided with a frame.

As illustrated in FIG. 4, a MEMS sensor 200 includes a sensor part 210, an upper cap 220, and a lower cap 230.

In more detail, the sensor part 210 includes a mass part 211, a flexible substrate 212, a support part 213, and a frame 214. In accordance with an embodiment, the frame 214 is selectively connected to the flexible substrate 212, the support part 213, and the mass part 211 and limits the displacement of the mass part 211, or is displaceably supported to the support part 213.

In accordance with an embodiment, the mass part 211, the flexible substrate 212, and the support part 213 are described with reference to the MEMS sensor, according to the embodiment of the invention illustrated in FIG. 3 and the detailed description thereof will be omitted.

In accordance with an embodiment, the upper cap 220 includes a substrate 221, a first negative photoresist 222, and a second negative photoresist 223 and is provided with a cavity 224.

In accordance with an embodiment, the lower cap 230 includes a substrate 231, a first negative photoresist 232, and a second negative photoresist 233 and is provided with a cavity 234.

In accordance with an embodiment, each component of the upper cap 220 and the lower cap 230 is described with reference to the upper cap and therefore the description thereof will be omitted.

By the above configuration, the MEMS sensor 100 including the cap module, according to the embodiment of the invention illustrated in FIG. 3, and the MEMS sensor 200, according to the embodiment of the invention illustrated in FIG. 4, includes the upper cap and the lower cap, which include the substrate, the first negative photoresist, and the second negative photoresist to ensure the accurate cavity depth to improve the sensing capability and is elaborately coupled with the sensor part to improve the reliability.

In accordance with an embodiment, the MEMS sensor 100 including the cap module, according to the embodiment of the invention illustrated in FIG. 3, and the MEMS sensor 200 according to the embodiment of the invention illustrated in FIG. 4, is configured to include one of the upper caps 120 and 220 and the lower caps 130 and 230 and the upper cap 120 and the lower cap 130 may adopt an IC wafer instead of the Si wafer.

According to various embodiments of the invention, it is possible to obtain the cap module for MEMS, which may have the reduced defective rate, the elaborate structure, and the improved productivity by forming the adhesive for coupling the cap to the MEMS device while forming the cavities by the first negative photoresist and the second negative photoresist, and it is possible to obtain the MEMS sensor, which has the improved sensing capability by ensuring the accurate cavity depth, including the upper cap and the lower cap including the substrate, the first negative photoresist, and the second negative photoresist and the improved reliability by then elaborate coupling with the sensor part.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A cap module for MEMS, comprising:
a substrate;
a first negative photoresist which is formed on one surface of the substrate; and
a second negative photoresist which is formed on one surface of the first negative photoresist.

2. The cap module for MEMS as set forth in claim 1, wherein the first negative photoresist and the second negative photoresist are each formed so that space parts formed with cavities correspond to each other.

3. The cap module for MEMS as set forth in claim 2, wherein the space part is formed by applying the same mask to the first negative photoresist and the second negative photoresist and exposing and developing the first negative photoresist and the second negative photoresist.

4. The cap module for MEMS as set forth in claim 1, wherein the first negative photoresist and the second negative photoresist are formed by spin coating and are formed to have a thickness by controlling an RPM.

5. The cap module for MEMS as set forth in claim 1, wherein the first negative photoresist is SU-8, which is an epoxy-based negative photoresist.

6. The cap module for MEMS as set forth in claim 1, wherein the second negative photoresist is liquid SINR.

7. A MEMS sensor, comprising:
a sensor part; and
a cap module, which is coupled with the sensor part to cover the sensor part,
wherein the cap module comprises a substrate, a first negative photoresist formed on one surface of the substrate, and a second negative photoresist formed on one surface of the first negative photoresist.

8. The MEMS sensor as set forth in claim 7, wherein the sensor part covered with the cap module comprises:
a mass part;
a flexible substrate, which is displaceably coupled with the mass part; and
a support part, which is coupled with the flexible substrate and floatably supports the mass part.

9. The MEMS sensor as set forth in claim 7, wherein the cap module covers the flexible substrate and comprises an upper cap, which is coupled with the flexible substrate and a lower cap, which covers the mass part and is coupled with the support part.

10. The MEMS sensor as set forth in claim 9, wherein the second negative photoresist of the upper cap is coupled with the flexible substrate and the second negative photoresist of the lower cap is supported with the support part.

11. The MEMS sensor as set forth in claim 7, wherein the first negative photoresist and the second negative photoresist are each formed to face each other in the sensor part so that space parts formed with cavities are formed to correspond to each other.

12. The MEMS sensor as set forth in claim 11, wherein the space part is formed by applying the same mask to the first negative photoresist and the second negative photoresist and exposing and developing the first negative photoresist and the second negative photoresist.

13. The MEMS sensor as set forth in claim 7, wherein the first negative photoresist and the second negative photoresist are formed by spin coating and are formed to have a thickness by controlling an RPM.

14. The MEMS sensor as set forth in claim 7, wherein the first negative photoresist is SU-8, which is an epoxy-based negative photoresist.

15. The MEMS sensor as set forth in claim 7, wherein the second negative photoresist is liquid SINR.

16. The MEMS sensor as set forth in claim 8, wherein the sensor part is further provided with a frame which is selectively connected to the flexible substrate, the support part, and the mass part and limits a displacement of the mass part or is displaceably supported to the support part.
